(19) United States
(12) Patent Application Publication
(10) Pub. No.: US 2025/0210937 A1
(43) Pub. Date: Jun. 26, 2025

(54) METHOD FOR MANUFACTURING LIGHT-EMITTING DEVICE AND LIGHT-EMITTING DEVICE

(71) Applicant: NICHIA CORPORATION, Anan-shi (JP)

(72) Inventors: Hironobu SHIBATA, Tokushima-shi (JP); Masatoshi NAKAGAKI, Komatsushima-shi (JP)

(21) Appl. No.: 18/991,233

(22) Filed: Dec. 20, 2024

(30) Foreign Application Priority Data
Dec. 25, 2023 (JP) 2023-217795

(51) Int. Cl. H01S 5/042; H01S 5/02315

(52) U.S. Cl. CPC H01S 5/04256; H01S 5/02315

(57) ABSTRACT

A method for manufacturing a light-emitting device includes: preparing a submount including a position specifying portion that specifies a position of a front surface; determining a first distance between a light-emitting end surface and a first alignment mark of a semiconductor laser element; disposing the semiconductor laser element so that the light-emitting end surface protrudes from the front surface of the submount in a top view; disposing a bridge-shaped member at a position overlapping with the light-emitting end surface and not overlapping with the first alignment mark and the position specifying portion; measuring a second distance between a position of the first alignment mark and a position of the front surface specified by the position specifying portion; calculating a third distance by subtracting the second distance from the first distance; and determining whether the light-emitting device is a defective product by comparing the third distance and a predetermined value.

### CROSS-REFERENCE TO RELATED APPLICATIONS

This application claims priority to Japanese Patent Application No. 2023-217795 filed on Dec. 25, 2023. The entire disclosure of Japanese Patent Application No. 2023-217795 is hereby incorporated herein by reference.

### TECHNICAL FIELD

The present disclosure relates to a method for manufacturing a light-emitting device and to a light-emitting device.

### BACKGROUND ART

Japanese Patent Publication No. 2000-98190 A discloses a light-emitting device including a submount including an upper surface, a semiconductor laser element provided on the upper surface of the submount and including a light-emitting end surface for emitting laser light, and a support member disposed facing the light-emitting end surface and supporting a lens, wherein the support member includes a portion overlapping with a portion of the semiconductor laser element in a top view.

### SUMMARY

An object of the present disclosure is to provide a method for manufacturing a light-emitting device with efficient heat dissipation, and a light-emitting device.

A method for manufacturing a light-emitting device according to an embodiment of the present disclosure includes: preparing a submount including an upper surface, a front surface connected to a front end of the upper surface, and a position specifying portion that specifies a position of the front surface in a top view; preparing a semiconductor laser element including a semiconductor structure having a light-emitting end surface, and a first electrode disposed on an upper surface of the semiconductor structure and provided with a first alignment mark; determining a first distance between the light-emitting end surface and the first alignment mark; disposing the semiconductor laser element on the upper surface of the submount after the first distance is determined, the semiconductor laser element being disposed so that the light-emitting end surface protrudes from the front surface of the submount in the top view; disposing a bridge-shaped member above the semiconductor laser element at a position overlapping with the light-emitting end surface and not overlapping with the first alignment mark and the position specifying portion in the top view; measuring a second distance between the first alignment mark and the front surface of the submount from a position of the first alignment mark and a position of the front surface of the submount specified by the position specifying portion; calculating a third distance between the light-emitting end surface and the front surface of the submount from a subtraction value obtained by subtracting the second distance from the first distance; and determining whether the light-emitting device is a sound product or a defective product by comparing the third distance and a predetermined value.

A light-emitting device according to an embodiment of the present disclosure includes a submount, a semiconductor laser element, and a bridge-shaped member. The submount includes an upper surface, a front surface connected to a front end of the upper surface, and a position specifying portion that specifies a position of the front surface in a top view. The semiconductor laser element is disposed on the upper surface of the submount. The semiconductor laser element includes a semiconductor structure provided with a light-emitting end surface protruding from the front surface of the submount in the top view, and a first electrode disposed on an upper surface of the semiconductor structure. The bridge-shaped member is disposed on the upper surface of the submount, the bridge-shaped member overlapping with the light-emitting end surface and not overlapping with the position specifying portion in the top view. The first electrode includes a first alignment mark disposed at a position spaced apart from the light-emitting end surface by a first distance on a side opposite to the light-emitting end surface relative to the front surface of the submount and at the position not overlapping with the bridge-shaped member in the top view.

According to an embodiment of the present disclosure, a method for manufacturing a light-emitting device with efficient heat dissipation and a light-emitting device can be provided.

### BRIEF DESCRIPTION OF DRAWINGS

FIG. 1 is a schematic top view illustrating an example of a light-emitting device according to a first embodiment.

FIG. 2 is a schematic front view illustrating an example of the light-emitting device according to the first embodiment.

FIG. 3 is a schematic cross-sectional view of a portion of the light-emitting device taken along line III-III in FIG. 1.

FIG. 4 is a schematic top view illustrating an example of a submount.

FIG. 5 is a schematic top view illustrating an example of a semiconductor laser element.

FIG. 6 is a schematic top view illustrating an example of an intermediate including the submount and the semiconductor laser element.

FIG. 7 is a schematic top view illustrating an example of the light-emitting device including the submount, the semiconductor laser element, and a bridge-shaped member.

FIG. 8 is a schematic top view illustrating an example of the light-emitting device including the submount, the semiconductor laser element, and the bridge-shaped member.

FIG. 9 is a schematic enlarged top view of the light-emitting device illustrating an enlarged region within a frame line IX of FIG. 8.

FIG. 10 is a schematic top view illustrating an example of a light-emitting device according to a second embodiment.

FIG. 11 is a schematic top view illustrating an example of a semiconductor laser element.

FIG. 12 is a schematic top view illustrating an example of the light-emitting device including the submount, the semiconductor laser element, and the bridge-shaped member.

### DETAILED DESCRIPTION

A method for manufacturing a light-emitting device and a light-emitting device according to embodiments of the present disclosure will be described below in detail with reference to the drawings. However, the following embodiments are examples of a method for manufacturing a light-emitting device and a light-emitting device embodying technical concepts of the embodiments, and limitation to the embodiments described below is not intended. Further, dimensions, materials, shapes, relative arrangements, or the like of constituent members described in the embodiments are not intended to limit the scope of the present disclosure thereto, unless otherwise specified, and are merely exemplary. Note that the size, positional relationship, or the like of members illustrated in each of the drawings may be exaggerated for clarity of description. In the following description, members having the same terms and reference signs represent the same members or members of the same quality, and a detailed description of these members is omitted as appropriate. As a cross-sectional view, an end view illustrating only a cut surface may be used.

In the following drawings, directions may be indicated by an X axis, a Y axis, and a Z axis. The X axis, the Y axis, and the Z axis are orthogonal to one another. The direction in the X-axis direction in which an arrow points is referred to as a +X direction or +X side and the direction opposite to the +X direction is referred to as a −X direction or −X side. The direction in the Y-axis direction in which an arrow points is referred to as a +Y direction or +Y side and the direction opposite to the +Y direction is referred to as a −Y direction or −Y side. The direction in the Z-axis direction in which an arrow points is referred to as a +Z direction or +Z side and the direction opposite to the +Z direction is referred to as a −Z direction or −Z side. In the embodiment, the +X direction is defined as “forward”, and the −X direction is defined as “backward”. In the embodiment, the +Z direction is referred to as “upward” and the −Z direction is referred to as “downward”. In the embodiments, a surface of a target object when viewed from the +X direction is referred as a “front surface”, a surface of a target object when viewed from the +Z direction is referred to as an “upper surface”, and a surface of the target object when viewed from the −Z direction is referred to as a “lower surface”. Also, the expression “in top view” used in the embodiments refers to viewing an object from the +Z direction. However, this does not limit the orientation of the light-emitting device during use, and the orientation of the light-emitting device may be any chosen orientation. In the following embodiments, “being aligned with the X axis, the Y axis, and the Z axis” includes an object having an inclination within a range of ±5° relative to the axes. In the embodiments, the orthogonality may include an error within ±5° with respect to 90°.

In the present disclosure, polygons such as triangles and quadrangles, including shapes in which the corners of the polygon are rounded, chamfered, beveled, coved, and the like, are referred to as polygons. A shape obtained by processing not only the corners (ends of a side) but also an intermediate portion of the side is similarly referred to as a polygon. That is, a shape that is partially processed while leaving the polygon as the base is included in the interpretation of the “polygon” described in the present disclosure.

The same applies not only to polygons but also to the terms representing specific shapes such as trapezoids, circles, protrusions, and recessions. The same also applies to the terms related to each side forming the shape. That is, even when processing is performed on a corner or an intermediate portion of a certain side, the interpretation of “side” includes the processed portion.

### First Embodiment

### Example of Overall Configuration of Light-Emitting Device 1

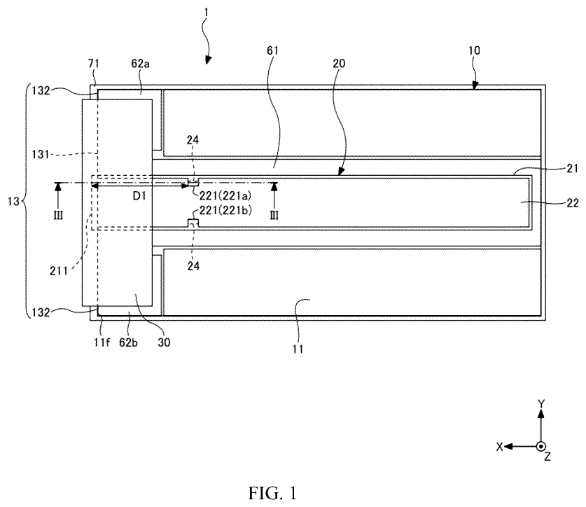

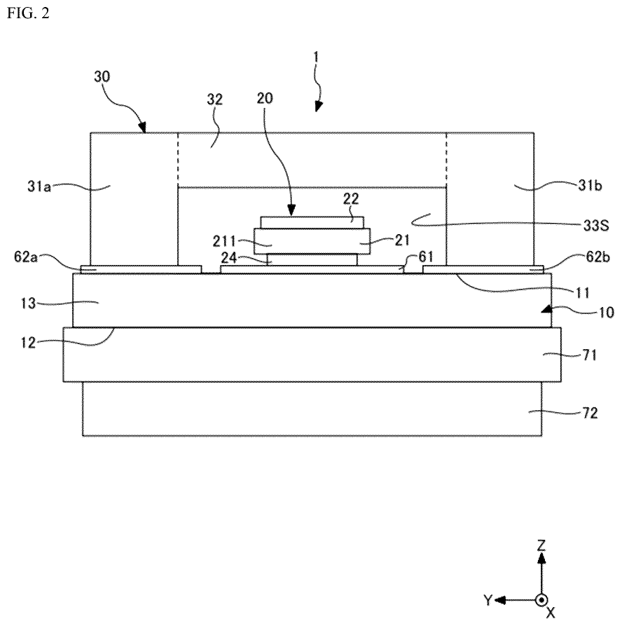

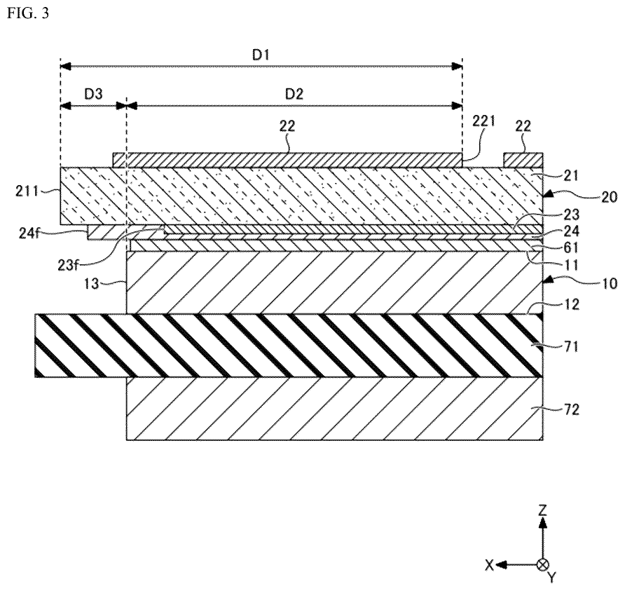

The overall configuration of a light-emitting device 1 according to a first embodiment is described with reference to FIGS. 1 to 3 and premised on the description of the method for manufacturing a light-emitting device according to the first embodiment. FIG. 1 is a schematic top view illustrating an example of the light-emitting device 1 according to the first embodiment. FIG. 2 is a schematic front view illustrating an example of the light-emitting device 1 according to the first embodiment. FIG. 3 is a schematic cross-sectional view of a portion of the light-emitting device 1 taken along line III-III in FIG. 1. Note that in FIG. 3, a bridge-shaped member 30 is omitted.

As illustrated in FIGS. 1 to 3, the light-emitting device 1 includes a submount 10, a semiconductor laser element 20, and the bridge-shaped member 30. The light-emitting device 1 may further include a film 61 disposed between the submount 10 and the semiconductor laser element 20, a first support member 71 supporting the submount 10, and a second support member 72 supporting the first support member 71. Furthermore, the light-emitting device 1 may include a package that houses components such as the submount 10, the semiconductor laser element 20, the bridge-shaped member 30, the first support member 71, and the second support member 72. The second support member 72 may be joined to the base of the package.

### Submount 10

The configuration of the submount 10 will now be described. The submount 10 includes an upper surface 11, a lower surface 12, and a plurality of lateral surfaces connecting the upper surface 11 and the lower surface 12. Among the plurality of lateral surfaces, the lateral surface connected to a front end 11f located at the most +X side of the upper surface 11 corresponds to a front surface 13. The illustrated submount 10 has a rectangular parallelepiped external shape. However, the submount 10 may have another shape such as a cylindrical shape.

The submount 10 supports the semiconductor laser element 20. Examples of the material constituting the submount 10 include ceramics such as silicon nitride (SiN), aluminum nitride (AlN), and silicon carbide (SiC) and metals such as copper (Cu). The illustrated submount 10 is constituted of copper. However, the material constituting the submount 10 is not limited thereto.

The length of the front surface 13 of the submount 10 along the Y-axis direction is preferably longer than the length of the bridge-shaped member 30 along the Y-axis direction. As illustrated in FIG. 1, the front surface 13 of the submount 10 preferably includes a first portion 131 overlapping with the bridge-shaped member 30 and a second portion 132 not overlapping with the bridge-shaped member 30 in a top view. That is, the second portion 132 of the front surface 13 can be visible without being blocked by the bridge-shaped member 30 in the top view. With this structure, even after the bridge-shaped member 30 is disposed on the submount 10, the position of the front surface 13 can be specified by the second portion 132 of the front surface 13. That is, the second portion 132 of the front surface 13 is a position specifying portion of the front surface 13. However, the position specifying portion is not limited thereto. Another example of the position specifying portion includes a mark or the like which is disposed at a position not overlapping with the bridge-shaped member 30 of the upper surface 11 of the submount 10 in a top view and is disposed at a position having a predetermined distance from the front surface 13. In this case, the length of the front surface 13 of the submount 10 along the Y-axis direction may be shorter than the length of the bridge-shaped member 30 along the Y-axis direction.

### Semiconductor Laser Element 20

The semiconductor laser element 20 will now be described. The semiconductor laser element 20 is the light source of the light-emitting device 1. The semiconductor laser element 20 is disposed on the submount 10 via the film 61 joined to the lower surface of the semiconductor laser element 20. As illustrated in FIGS. 2 and 3, the semiconductor laser element 20 includes a semiconductor structure 21, a first electrode 22, a second electrode 23, and a pad electrode 24.

The semiconductor structure 21 includes an upper surface, a lower surface, and a plurality of lateral surfaces connecting the upper surface and the lower surface. The illustrated semiconductor structure 21 has a rectangular parallelepiped external shape. However, the semiconductor structure 21 may have another shape.

The semiconductor structure 21 includes a semiconductor layer of a first conductivity type, an active layer, and a semiconductor layer of a second conductivity type that are stacked along the Z-axis direction. The first conductivity type may be either n-type or p-type. The second conductivity type is a conductivity type opposite to the first conductivity type. In other words, when the first conductivity type is n-type, the second conductivity type is p-type. When the first conductivity type is p-type, the second conductivity type is n-type. The semiconductor layer of the first conductivity type, the active layer, and the semiconductor layer of the second conductivity type in the semiconductor structure 21 are constituted of, for example, a nitride-based semiconductor such as In_{X}Al_{Y}Ga_{1-X-Y}N (0≤X, 0≤Y, X+Y≤1). However, the material constituting the semiconductor structure 21 is not limited thereto.

The light emitted by the semiconductor structure 21 is emitted from, among the plurality of lateral surfaces of the semiconductor structure 21, the front surface connecting the front ends located at the most +X side of the upper surface and the lower surface. The front surface of the semiconductor structure 21 corresponds to a light-emitting end surface 211. When a current is injected through the first electrode 22 and the second electrode 23, the semiconductor structure 21 emits light from the light-emitting end surface 211 to the +X side. As illustrated in FIG. 3, the light-emitting end surface 211 protrudes from the front surface 13 of the submount 10 in a top view. That is, the light-emitting end surface 211 is located on the +X side of the front surface 13 of the submount 10 in the top view. Since the light-emitting end surface 211 protrudes from the front surface 13 of the submount 10, it is possible to prevent the submount 10 from overlapping with the irradiation range of the light emitted from the light-emitting end surface 211. As a result, it is possible to suppress a situation in which the light emitted from the light-emitting end surface 211 is reflected by the submount 10 to cause a decrease in the intensity of the light in a desired irradiation range, a disturbance of a light distribution pattern, or the like.

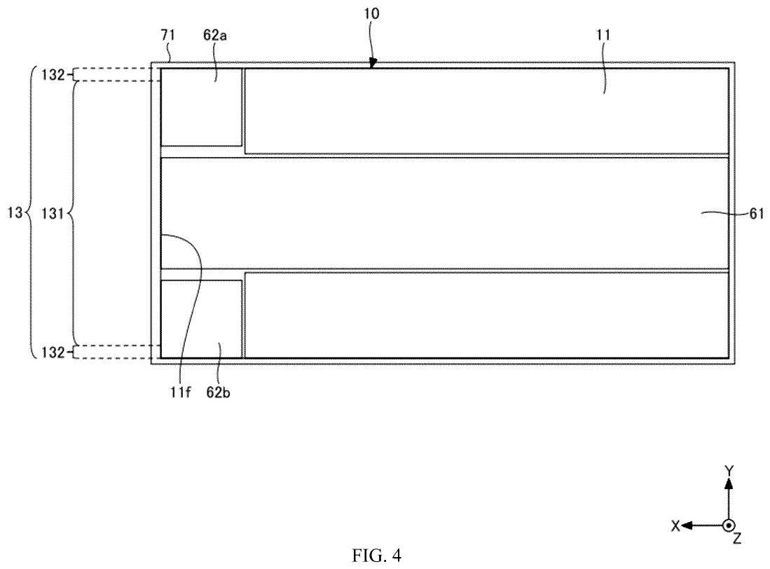

On the other hand, if the light-emitting end surface 211 protrudes too much from the front surface 13 of the submount 10, the front region (region on the +X side) of the semiconductor laser element 20 including the light-emitting end surface 211 has an increased region that is not joined to the upper surface 11 of the submount 10. Thus, the heat dissipation efficiency of the heat generated in the semiconductor laser element 20 is decreased, which may cause problems such as a decrease in the brightness of the light emitted from the light-emitting end surface 211 and damage to the semiconductor laser element 20. In order to suppress these problems, it is preferable that the distance between the light-emitting end surface 211 and the front surface 13 of the submount 10 stay within a predetermined range. A method for keeping the distance between the light-emitting end surface 211 and the front surface 13 of the submount 10 within the predetermined range will be described separately with reference to FIGS. 4 to 8.

The first electrode 22 is disposed on the upper surface of the semiconductor structure 21. The first electrode 22 is electrically connected to the semiconductor layer of the first conductivity type located at the most +Z side among the semiconductor layer of the first conductivity type, the active layer, and the semiconductor layer of the second conductivity type included in the semiconductor structure 21. When the semiconductor layer of the first conductivity type is an n-type semiconductor layer, the first electrode 22 corresponds to an n-side electrode. When the semiconductor layer of the first conductivity type is a p-type semiconductor layer, the first electrode 22 corresponds to a p-side electrode. Hereinafter, the semiconductor layer of the first conductivity type is an n-type semiconductor layer, and the first electrode 22 is an n-side electrode.

Examples of the material constituting the first electrode 22 include a metal material such as gold (Au), silver (Ag), copper (Cu), aluminum (Al), nickel (Ni), rhodium (Rh), titanium (Ti), platinum (Pt), palladium (Pd), molybdenum (Mo), chromium (Cr), and tungsten (W). However, the material constituting the first electrode 22 is not limited thereto.

As illustrated in FIGS. 1 and 3, the first electrode 22 includes a first alignment mark 221. The first alignment mark 221 is disposed at a position away from the light-emitting end surface 211 in the −X direction by a distance D1 on the side opposite to the light-emitting end surface 211 relative to the front surface 13 of the submount 10 in a top view. That is, the first alignment mark 221 is disposed at a position on the −X side of the light-emitting end surface 211 and away from the light-emitting end surface 211 in the −X direction by the distance D1. Here, the distance between the light-emitting end surface 211 and the first alignment mark 221 is, for example, a distance between the light-emitting end surface 211 and a side of the first alignment mark 221 that is at the most +X side among the sides parallel to the light-emitting end surface 211. The first alignment mark 221 is disposed at a position not overlapping with the bridge-shaped member 30 in a top view. The distance D1 is an example of a “first distance”.

In the illustrated example, two first alignment marks 221a and 221b are provided. However, the number of first alignment marks 221 is not limited to two. In other words, the number of first alignment marks 221 may also be one or three or more. When a plurality of the first alignment marks 221 are provided, at least one line segment connecting two first alignment marks 221 among the plurality of first alignment marks 221 is preferably parallel to the light-emitting end surface 211 of the semiconductor structure 21. In the illustrated example, the line segment connecting the first alignment mark 221a and the first alignment mark 221b is parallel to the light-emitting end surface 211 of the semiconductor structure 21.

The first alignment mark 221a is a notch that is cut inward from the outer edge of the first electrode 22 on the +Y side. The first alignment mark 221b is a notch that is cut inward from the outer edge of the first electrode 22 on the −Y side. However, the configuration of the first alignment marks 221a and 221b is not limited thereto. The first alignment marks 221a and 221b may be, for example, holes or the like having another shape such as a substantially circular shape, a substantially elliptical shape, or a substantially polygonal shape, which are disposed inside the first electrode 22 so as not to be in contact with the outer edge of the first electrode 22. The first alignment marks 221a and 221b can be easily formed by forming the first alignment marks 221a and 221b as regions vertically penetrating the first electrode 22 in the form of a notch or hole. However, the first alignment marks 221a and 221b may not be regions vertically penetrating the first electrode 22. For example, the first alignment marks 221a and 221b may be patterns of a conductive film formed on the upper surface of the first electrode 22.

The second electrode 23 is disposed on the lower surface of the semiconductor structure 21. The second electrode 23 is electrically connected to the semiconductor layer of the second conductivity type located at the most −Z side among the semiconductor layer of the first conductivity type, the active layer, and the semiconductor layer of the second conductivity type included in the semiconductor structure 21. When the semiconductor layer of the second conductivity type is a p-type semiconductor layer, the second electrode 23 corresponds to a p-side electrode. When the semiconductor layer of the second conductivity type is an n-type semiconductor layer, the second electrode 23 corresponds to an n-side electrode. Hereinafter, the semiconductor layer of the second conductivity type is a p-type semiconductor layer, and the second electrode 23 is a p-side electrode. The material constituting the second electrode 23 may be the same as or different from that of the first electrode 22.

As illustrated in FIG. 3, a front end 23f of the second electrode 23 is located on the −X side relative to the front surface 13 of the submount 10. Accordingly, even when the light-emitting end surface 211 protrudes from the front surface 13 of the submount 10, the entire region of the lower surface of the second electrode 23 can be overlapped with the upper surface 11 of the submount 10 in a top view. The second electrode 23 is a member through which a current passes during the light-emitting operation of the semiconductor laser element 20. That is, the second electrode 23 generates heat during the light-emitting operation of the semiconductor laser element 20. By overlapping the entire region of the lower surface of the second electrode 23 with the upper surface 11 of the submount 10, the heat generated in the second electrode 23 during the light-emitting operation can be efficiently dissipated to the outside through the submount 10.

The pad electrode 24 is electrically connected to the second electrode 23 and, of the semiconductor layer of the first conductivity type, the active layer, and the semiconductor layer of the second conductivity type included in the semiconductor structure 21, the semiconductor layer of the second conductivity type located at the most −Z side. The illustrated pad electrode 24 is disposed in contact with the lower surface of the semiconductor structure 21 and the second electrode 23. At least a portion of the pad electrode 24 overlaps with the second electrode 23 in a top view. Specifically, the pad electrode 24 covers the lower surface and the lateral surface of the second electrode 23. The material constituting the pad electrode 24 may be the same as that of the second electrode 23. However, the configuration of the pad electrode 24 is not limited thereto.

### Bridge-Shaped Member 30

The configuration of the bridge-shaped member 30 will now be described. As illustrated in FIGS. 1 and 2, the bridge-shaped member 30 is disposed on the upper surface 11 of the submount 10 straddling the semiconductor laser element 20. The bridge-shaped member 30 is disposed overlapping with the light-emitting end surface 211 of the semiconductor structure 21 and a portion of the front surface 13 of the submount 10 in a top view. Of the front surface 13 of the submount 10, in a top view, the portion overlapping with the bridge-shaped member 30 may be the first portion 131, and the non-overlapping portion may be the second portion 132.

As illustrated in FIG. 2, the bridge-shaped member 30 includes two leg portions 31a and 31b extending from the upper surface 11 of the submount 10 toward the +Z side, and a beam portion 32 connected to the upper side of the inner lateral surface of the leg portion 31a and the upper side of the inner lateral surface of the leg portion 31b. A space 33S penetrating the bridge-shaped member 30 in the X-axis direction is formed in a region surrounded by the leg portion 31a, the leg portion 31b, and the beam 32.

The leg portion 31a, the leg portion 31b, and the beam 32 may be a series of structurally integrated members. Further, the leg portion 31a, the leg portion 31b, and the beam 32 may be separate members. The lower surface of the leg portion 31a may be joined to the upper surface 11 of the submount 10 via a film 62a. The lower surface of the leg portion 31b may be joined to the upper surface 11 of the submount 10 via a film 62b.

The bridge-shaped member 30 may support, for example, an optical member such as a lens. The optical member such as a lens is disposed, for example, on the +X side of the space 33S and overlaps with the space 33S in a side view as seen from the +X side. The optical member such as a lens may be joined to the front surface of the leg portion 31a and the front surface of the leg portion 31b. Thus, the bridge-shaped member 30 can support the optical member such as a lens such that the optical member such as a lens and the light-emitting end surface 211 of the semiconductor structure 21 face each other.

### Film 61

The film 61 is a member that joins the upper surface 11 of the submount 10 and the lower surface of the semiconductor laser element 20. Examples of the material constituting the film 61 include metal materials such as Au, Ag, Cu, Al, Ni, Rh, Ti, Pt, Pd, Mo, Cr, and W and alloy materials such as AuSn, SnCu, SnAg, and SnAgCu. However, the material constituting the film 61 is not limited thereto.

The film 61 may be electrically connected to the second electrode 23 and the pad electrode 24. Alternatively, the film 61 may be joined to one end of a conductive wire extending from an external connection terminal such as a lead terminal. The external connection terminal is electrically connected to an external power source. In this case, the film 61 corresponds to a portion of a current path for supplying power to the semiconductor laser element 20.

### First Support Member 71 and Second Support Member 72

The first support member 71 includes an upper surface, a lower surface, and a plurality of lateral surfaces connecting the upper surface and the lower surface. The first support member 71 has, for example, a rectangular parallelepiped external shape. The upper surface of the first support member 71 is joined to the lower surface 12 of the submount 10. The second support member 72 includes an upper surface, a lower surface, and a plurality of lateral surfaces connecting the upper surface and the lower surface. The second support member 72 has, for example, a rectangular parallelepiped external shape. The upper surface of the second support member 72 is joined to the lower surface of the first support member 71. The semiconductor laser element 20 is supported by three members stacked in the Z-axis direction, including the submount 10, the first support member 71, and the second support member 72.

The first support member 71 and the second support member 72 are preferably constituted of a material having excellent heat dissipation properties such as SiN, AlN, SiC, and Cu. The illustrated first support member 71 is constituted of an insulating material such as AlN. Thus, the semiconductor laser element 20 can be electrically separated from the second support member 72, and the second support member 72 can be used only for heat dissipation. The illustrated second support member 72 is constituted of Cu. Since the first support member 71 and the second support member 72 are constituted of a material having excellent heat dissipation properties, heat from the semiconductor laser element 20 can be efficiently dissipated to the outside through the submount 10, the first support member 71, and the second support member 72. However, the material constituting the first support member 71 and the second support member 72 is not limited thereto.

As illustrated in FIG. 3, the front surface of the first support member 71 is located on the +X side with respect to the front surface 13 of the submount 10 and the front surface of the second support member 72. However, the position of the front surface of the first support member 71 in the X-axis direction may be substantially the same as the positions of the front surface 13 of the submount 10 and the front surface of the second support member 72 in the X-axis direction. Alternatively, the first support member 71 and the second support member 72 may be omitted, and only the submount 10 may support the semiconductor laser element 20.

### Method for Manufacturing Light-Emitting Device 1

An example of a method for manufacturing the light-emitting device 1 according to the first embodiment will be described. The method for manufacturing the light-emitting device 1 according to the first embodiment includes: preparing the submount 10, preparing the semiconductor laser element 20, determining the distance D1 in the X-axis direction between the light-emitting end surface 211 of the semiconductor structure 21 and the first alignment mark 221 of the semiconductor laser element 20, disposing the semiconductor laser element 20 on the upper surface 11 of the submount 10, disposing the bridge-shaped member 30 on the upper surface 11 of the submount 10, measuring a distance D2 in the X-axis direction between the first alignment mark 221 and the front surface 13 of the submount 10, calculating a distance D3 in the X-axis direction between the light-emitting end surface 211 and the front surface 13 of the submount 10, and determining whether the light-emitting device 1 is a sound (non-defective) product or a defective product by comparing the distance D3 and a predetermined value.

Determining the distance D1 in the X-axis direction between the light-emitting end surface 211 of the semiconductor structure 21 and the first alignment mark 221 of the semiconductor laser element 20 is hereinafter referred to as “determining the distance D1”. Measuring the distance D2 in the X-axis direction between the first alignment mark 221 and the front surface 13 of the submount 10 is hereinafter referred to as “measuring the distance D2”. Determining whether the light-emitting device 1 is a sound product or a defective product by comparing the distance D3 and the predetermined value is hereinafter referred to as “determining whether sound or defective”. The distance D2 is an example of a “second distance”. The distance D3 is an example of a “third distance”.

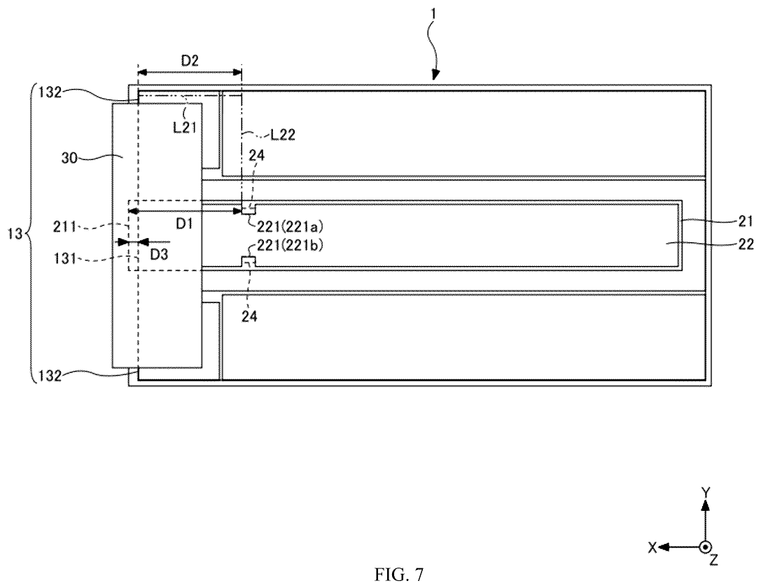

Preparing the submount 10 will now be described with reference to FIG. 4. FIG. 4 is a schematic top view illustrating an example of the submount 10. As illustrated in FIG. 4, the submount 10 includes the upper surface 11 and the front surface 13 connecting to the front end 11f of the upper surface 11. In addition, the front surface 13 includes the first portion 131 overlapping with the bridge-shaped member 30 described separately with reference to FIG. 7 and the second portion 132 not overlapping with the bridge-shaped member 30 in a top view. The second portion 132 is used to specify the front surface 13 of the submount 10 after the bridge-shaped member 30 has been disposed.

In preparing the submount 10, the film 61, the film 62a, and the film 62b may be formed on the upper surface 11 of the submount 10 using a vapor deposition method such as sputtering, a plating method, or the like. In preparing the submount 10, the first support member 71 may be joined to the lower surface 12 of the submount 10. Further, the second support member 72 may be joined to the lower surface of the first support member 71.

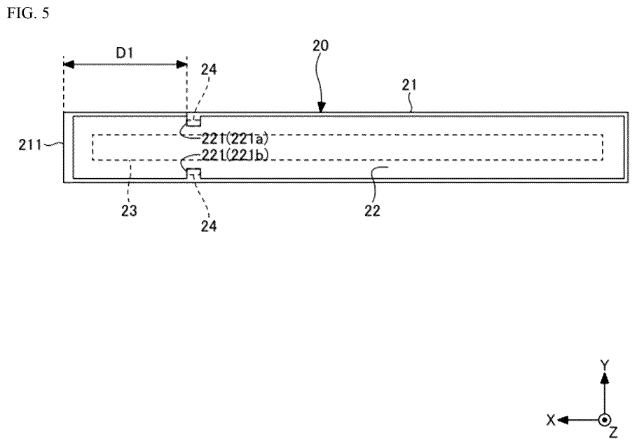

Subsequently, preparing the semiconductor laser element 20 and determining the distance D1 will be described with reference to FIG. 5. FIG. 5 is a schematic top view illustrating an example of the semiconductor laser element 20. Note that preparing the semiconductor laser element 20 and determining the distance D1 may be performed before preparing the submount 10 or after.

As illustrated in FIG. 5, the semiconductor laser element 20 includes the semiconductor structure 21 including the light-emitting end surface 211 and the first electrode 22 disposed on the upper surface of the semiconductor structure 21. The first electrode 22 includes the first alignment mark 221.

In preparing the semiconductor laser element 20, the first alignment mark 221 may be formed on the first electrode 22 using any method. For example, the first electrode 22 may be formed with a masking member such as a resist covering a portion of the upper surface of the semiconductor structure 21. Then, by removing the masking member, the first alignment mark 221 may be formed. Alternatively, the first alignment mark 221 may be formed by forming the first electrode 22 on the upper surface of the semiconductor structure 21 and thereafter removing a portion of the first electrode 22 by reactive ion etching, wet etching, laser, or another cutting method. Also, the first alignment mark 221 may be formed by providing a pattern of a conductor film on the first electrode 22. However, the method for forming the first alignment mark 221 on the first electrode 22 is not limited thereto. The first alignment marks 221 formed on the first electrode 22 is formed at a position away from the light-emitting end surface 211 by the distance D1 in the −X direction.

After the semiconductor laser element 20 is prepared, the distance D1 is determined. Here, the distance D1 is, for example, the shortest distance from the frontmost portion (the portion located at the most +X side) of the first alignment mark 221 to the light-emitting end surface 211. However, the distance D1 may be the distance between another portion of the first alignment mark 221 and the light-emitting end surface 211.

The distance D1 is preferably determined, for example, by being measured using a measuring unit such as an image measurement device. The image measurement device includes, for example, an imaging unit that captures an image of an observation target and a processing unit that measures the distance between two points of the observation target on the basis of image data output from the imaging unit. The imaging unit includes, for example, an imaging optical system including an objective lens and an image sensor. The processing unit includes a computation processing device including a central processing unit (CPU), a memory, and the like. The processing unit may be a configuration unit capable of executing processing other than measuring the distance between two points of the observation target. The processing unit may be an information processing apparatus such as a personal computer (PC) provided adjacent to the imaging unit, or may be an information processing apparatus provided at a position away from the imaging unit such as an external server. Note that the distance D1 may not be a value obtained by measurement and may be a predetermined value. By setting the distance D1 to a predetermined value, measuring the distance D1 can be omitted. In this case, setting the distance D1 to a predetermined value corresponds to determining the distance D1. On the other hand, when the value of the distance D1 is obtained by measurement, an accurate value for the distance D1 can be obtained for each semiconductor laser element 20.

A method for measuring the distance D1 using the image measurement device is as follows, for example. First, the imaging unit of the image measurement device is disposed above the semiconductor laser element 20 and is caused to face, for example, the front region (region on the +X side) of the upper surface of the semiconductor laser element 20. Subsequently, the imaging unit of the image measurement device captures an image including at least the light-emitting end surface 211 and the first alignment marks 221a and 221b. Subsequently, the imaging unit outputs the image data including the light-emitting end surface 211 and the first alignment marks 221a and 221b to the processing unit. Subsequently, the processing unit measures the distance D1 between the light-emitting end surface 211 and the first alignment mark 221a or between the light-emitting end surface 211 and the first alignment mark 221b on the basis of the image data output from the imaging unit. Here, via analysis of the image data, the processing unit may automatically specify the position of the light-emitting end surface 211 and the positions of the first alignment marks 221a and 221b and measure the distance D1 from both pieces of specified position information. Also, the processing unit may measure the distance D1 on the basis of the position information of the light-emitting end surface 211 and the position information of the first alignment marks 221a and 221b input by an operator. The processing unit stores information of the measured distance D1.

The image measurement device may measure only the distance D1 between the first alignment mark 221a and the light-emitting end surface 211. Also, the image measurement device may measure only the distance D1 between the first alignment mark 221b and the light-emitting end surface 211. Further, the image measurement device may measure both the distance D1 between the first alignment mark 221a and the light-emitting end surface 211 and the distance D1 between the first alignment mark 221b and the light-emitting end surface 211. Further, when the first alignment mark 221 is formed in addition to the first alignment marks 221a and 221b, the image measurement device may measure the distance D1 between the other first alignment mark 221 and the light-emitting end surface 211. In addition, the image measurement device may measure a distance between a line segment connecting the first alignment mark 221a and the first alignment mark 221b and the light-emitting end surface 211 and set this distance as the distance D1.

When the first alignment marks 221a and 221b are disposed near the light-emitting end surface 211, the first alignment marks 221a and 221b and the light-emitting end surface 211 can be included in one high-resolution image even if the field of view of the imaging unit of the image measurement device is narrowed. As a result, the position information of the first alignment marks 221a and 221b and the position information of the light-emitting end surface 211 are specified with high accuracy. Accordingly, the distance D1 measurement accuracy can be increased.

From the viewpoint of increasing the distance D1 measurement accuracy, the distance D1 is preferably equal to or less than 1000 μm, more preferably equal to or less than 700 μm, and still more preferably equal to or less than 500 μm. However, the distance D1 is not limited thereto.

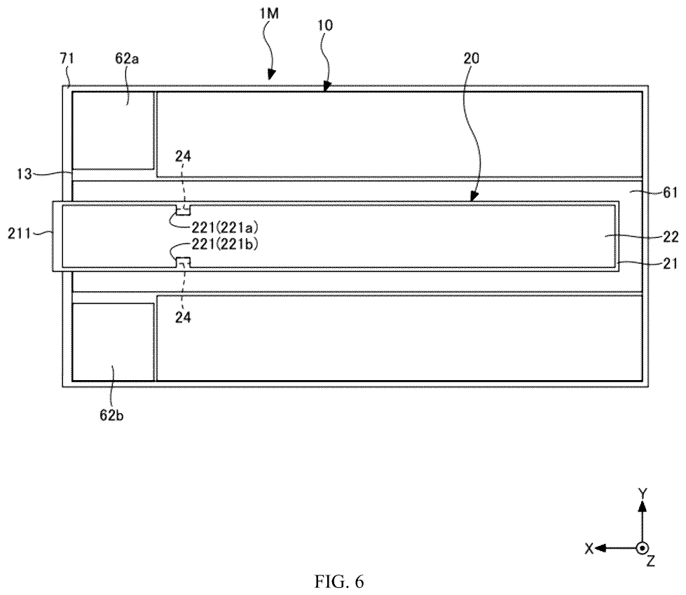

Subsequently, disposing the semiconductor laser element 20 will be described with reference to FIG. 6. FIG. 6 is a schematic top view illustrating an example of an intermediate 1M including the submount 10 and the semiconductor laser element 20.

Disposing the semiconductor laser element 20 is performed after determining the distance D1. As illustrated in FIG. 6, the semiconductor laser element 20 is disposed such that the light-emitting end surface 211 protrudes from the front surface 13 of the submount 10 in a top view. The light-emitting end surface 211 is located on the +X side with respect to the front surface 13 of the submount 10.

Subsequently, disposing the bridge-shaped member 30 and measuring the distance D2 will be described with reference to FIG. 7. FIG. 7 is a schematic top view illustrating an example of the light-emitting device 1 including the submount 10, the semiconductor laser element 20, and the bridge-shaped member 30.

As illustrated in FIG. 7, the bridge-shaped member 30 is disposed above the semiconductor laser element 20 at a position overlapping with the light-emitting end surface 211 and not overlapping with the first alignment mark 221 in a top view. Here, in a top view, the bridge-shaped member 30 overlaps with the first portion 131 of the front surface 13 of the submount 10 but does not overlap with the second portion 132. In other words, the second portion 132 of the front surface 13 of the submount 10 is not blocked by the bridge-shaped member 30 and is visible in a top view.

Although the value of the distance D3 can be obtained if the light-emitting end surface 211 can be directly measured from after the semiconductor laser element 20 is disposed on the submount 10 and until the bridge-shaped member 30 is disposed, there may actually be a case where the light-emitting end surface 211 cannot be directly measured from after the semiconductor laser element 20 is disposed on the submount 10 and until the bridge-shaped member 30 is disposed. For example, an example of a method for joining the semiconductor laser element 20 and the submount 10 to each other includes the semiconductor laser element 20 being brought into contact with the upper surface 11 of the submount 10 via the film 61, and thereafter, the semiconductor laser element 20 and the submount 10 being heated and pressed against each other. “Heating and pressing” does not limit the order of the timing of heating and the timing of pressing and includes all cases including heating and then pressing in a heated state, pressing and then heating in a pressed state, and simultaneously heating and pressing. Here, by heating the film 61 when the semiconductor laser element 20 and the submount 10 are joined to each other, the film 62a is also heated at the same time. When the film 62a is heated for a predetermined amount of time without being in contact with the lower surface of the leg portion 31a, the joining properties of the film 62a are degraded due to a change in composition. Thereafter, the bridge-shaped member 30 and the submount 10 may be unable to be joined together even if joining of the bridge-shaped member 30 and the submount 10 via heating and pressing is attempted again. The same also applies to the film 62b. Thus, it is preferable that the joining between the semiconductor laser element 20 and the submount 10 and the joining between the bridge-shaped member 30 and the submount 10 be performed at the same time or within a predetermined amount of time. In this case, there is no time for disposing the semiconductor laser element 20 and directly measuring the distance between the light-emitting end surface 211 and the front surface 13 of the submount 10. Thus, as will be described later, it is preferable to calculate the value of the distance D3 using the distance D1 and the distance D2. Even if the semiconductor laser element 20 is brought into contact with the upper surface 11 of the submount 10 via the film 61 and the distance D3 is measured before heating, there is a possibility that the relative position of the semiconductor laser element 20 with respect to the submount 10 may be shifted due to the subsequent heating and pressing. Thus, it is preferable to measure the distance D3 in a state where joining has been completed.

By disposing the bridge-shaped member 30, the light-emitting device 1 is assembled. However, the light-emitting end surface 211 of the semiconductor structure 21 overlaps with the bridge-shaped member 30 in a top view. Thus, after the light-emitting device 1 is assembled, the positional relationship between the light-emitting end surface 211 and the front surface 13 of the submount 10 cannot be directly checked visually or by an image measurement device. That is, from the viewpoint of the irradiation range of the light emitted from the light-emitting end surface 211, the positional relationship with the submount 10, and the heat dissipation efficiency of the heat generated in the semiconductor laser element 20, it is impossible to directly check whether the distance between the light-emitting end surface 211 disposed on the +X side and the front surface 13 of the submount 10 falls within a predetermined preferable range by visual observation or by an image measurement device. Thus, the following, including measuring the distance D2, are performed.

After the bridge-shaped member 30 is disposed, the distance D2 is measured. A method for measuring the distance D2 between the first alignment mark 221a, from among the two first alignment marks 221 formed on the first electrode 22, and the front surface 13 of the submount 10 will be described as an example. Here, in FIG. 7, the distance D2 may be, for example, the distance in the X-axis direction between the second portion 132 and an imaginary line L22 extending along the Y-axis direction from the frontmost portion (the portion located at the most +X side) of the first alignment mark 221a. However, the distance D2 is not limited thereto. The distance D2 may be the distance between another portion of the first alignment mark 221a and the second portion 132.

The distance D2 is preferably measured, for example, using an image measurement device. If the distance D1 is determined by measurement, the distance D2 is preferably measured using the image measurement device that measured the distance D1. A method for measuring the distance D2 using the image measurement device is as follows, for example. First, the imaging unit of the image measurement device is disposed above the light-emitting device 1 and is caused to face, for example, the front region (region on the +X side) of the light-emitting device 1. Subsequently, the imaging unit of the image measurement device captures an image including at least the second portion 132 at the front surface 13 of the submount 10 and the first alignment mark 221a. Subsequently, the imaging unit outputs the image data including the second portion 132 and the first alignment mark 221a to the processing unit. Subsequently, the processing unit measures the distance D2 in the X-axis direction between the front surface 13 of the submount 10 whose position is specified from the second portion 132 and the first alignment mark 221a on the basis of the image data output from the imaging unit. Here, the processing unit may automatically measure the distance D2 by analyzing the image data. Also, the processing unit may measure the distance D2 on the basis of the position information of the second portion 132 and the position information of the first alignment mark 221a input by an operator. The processing unit stores information of the measured distance D2. The image measurement device may execute similar processing to measure the distance D2 between the first alignment mark 221b and the front surface 13 of the submount 10.

Since the first alignment marks 221a and 221b are disposed near the front surface 13 of the submount 10, the first alignment marks 221a and 221b and the second portion 132 of the front surface 13 can be included in one high-resolution image even if the field of view of the imaging unit of the image measurement device is narrowed. Accordingly, the position information of the first alignment marks 221a and 221b and the position information of the second portion 132 can be specified with high accuracy. As a result, the accuracy of the distance D2 measurement can be increased.

After measuring the distance D2, the distance D3 between the light-emitting end surface 211 and the front surface 13 of the submount 10 is calculated. Here, the light-emitting end surface 211 is covered with the bridge-shaped member 30 and is in a state of not being visible in a top view. Thus, the calculated distance D3 corresponds to an estimated value of the actual distance between the light-emitting end surface 211 and the front surface 13 of the submount 10.

To be more specific, for example, the processing unit of the image measurement device refers to the distance D1 and the distance D2 related to the first alignment mark 221a stored in a storage unit and obtains a subtraction value obtained by subtracting the distance D2 from the distance D1. The subtraction value obtained by the image measurement device is set as the distance D3 between the light-emitting end surface 211 and the front surface 13 of the submount 10. The processing unit of the image measurement device may calculate the distance D3 by referencing the distance D1 and the distance D2 related to the first alignment mark 221b. When the first alignment mark 221 is formed in addition to the first alignment marks 221a and 221b, the processing unit of the image measurement device may calculate the distance D3 by referencing the distance D1 and the distance D2 related to the other first alignment mark 221. The processing unit of the image measurement device may select the average value of a plurality of the distances D3 calculated on the basis of the distance D1 and the distance D2 to the first alignment mark 221 as the final distance D3.

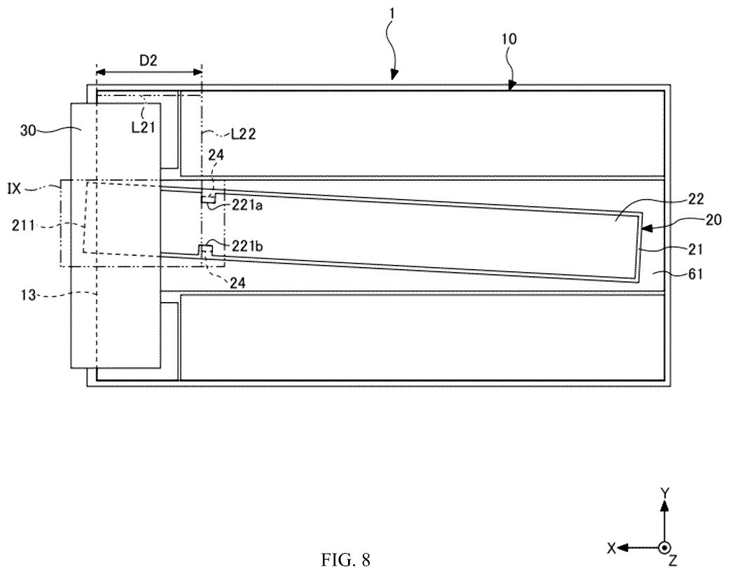

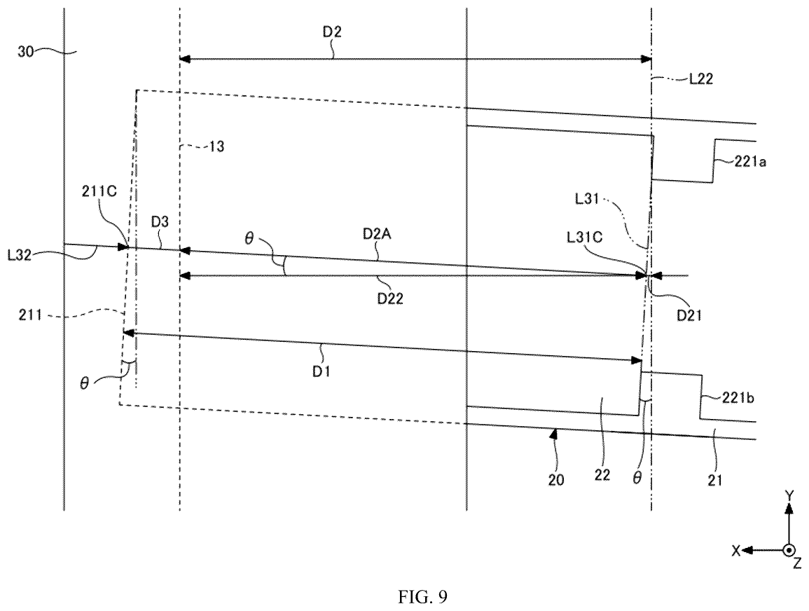

In addition, for example, when the semiconductor laser element 20 is disposed in a state where the light-emitting end surface 211 is inclined with respect to the front surface 13 of the submount 10, correcting the distance D3 may be performed. Correcting the distance D3 may be performed using an image measurement device. Correcting the distance D3 will be described with reference to FIGS. 8 and 9. FIG. 8 is a schematic top view illustrating an example of the light-emitting device 1 including the submount 10, the semiconductor laser element 20, and the bridge-shaped member 30. FIG. 9 is a schematic enlarged top view of the light-emitting device 1 illustrating an enlarged region within a frame line IX of FIG. 8.

As a premise, as illustrated in FIG. 9, a line segment L31 connecting the two first alignment marks 221a and 221b is parallel to the light-emitting end surface 211. As illustrated in FIG. 9, the light-emitting end surface 211 is inclined at an angle θ with respect to the front surface 13 of the submount 10. The front surface 13 of the submount 10 extends along the Y-axis direction. When the light-emitting end surface 211 is inclined with respect to the front surface 13 of the submount 10, the distance D1 is, for example, the distance of a line segment inclined at an angle θ with respect to the X-axis direction and connecting the line segment L31 and the light-emitting end surface 211 in the shortest distance.

As an example, a method for correcting the distance D3 calculated on the basis of the distance D1 and the distance D2 related to the first alignment mark 221a will be described. The processing unit of the image measurement device specifies, for example, the X coordinate and the Y coordinate of the first alignment mark 221a and the X coordinate and the Y coordinate of the first alignment mark 221b from the image data obtained when measuring the distance D2. Subsequently, the processing unit of the image measurement device obtains the angle θ formed by the line segment L31 connecting the first alignment mark 221a and the first alignment mark 221b and the front surface 13 of the submount 10 from the X coordinate and the Y coordinate of the first alignment mark 221a and the X coordinate and the Y coordinate of the first alignment mark 221b. Since the line segment L31 and the light-emitting end surface 211 are parallel to each other, the angle θ formed by the line segment L31 and the front surface 13 of the submount 10 corresponds to the angle θ of the light-emitting end surface 211 with respect to the front surface 13 of the submount 10. In addition, the processing unit of the image measurement device obtains, for example, the X coordinate of a midpoint L31C of the line segment L31 (hereinafter referred to as “midpoint L31”) from the average value of the X coordinate of the first alignment mark 221a and the X coordinate of the first alignment mark 221b. Subsequently, the processing unit of the image measurement device obtains a distance D21 between the first alignment mark 221a and the midpoint L31C in the X-axis direction from the difference between the X coordinate of the first alignment mark 221a and the X coordinate of the midpoint L31C. Subsequently, the processing unit of the image measurement device subtracts the distance D21 from the distance D2 to obtain a distance D22 between the midpoint L31C and the front surface 13 of the submount 10 in the X-axis direction. Subsequently, on the basis of the angle θ and the distance D22, the processing unit of the image measurement device obtains a distance D2A between the midpoint L31C and the front surface 13 of the submount 10 on a line segment L32 passing through the midpoint L31C and a center 211C of the light-emitting end surface 211. Subsequently, the processing unit of the image measurement device corrects the distance D3 to a subtraction value obtained by subtracting the distance D1 from the distance D2A. In this manner, by correcting the distance D3 including the information of the angle θ between the light-emitting end surface 211 and the front surface 13 of the submount 10, the estimation accuracy of the distance D3 can be further improved.

The processing unit of the image measurement device may correct the distance D3 on the basis of the distance D1, the distance D2, and the angle θ related to the first alignment mark 221b. Also, when the first alignment mark 221 is formed in addition to the first alignment marks 221a and 221b, the processing unit of the image measurement device may correct the distance D3 on the basis of the distance D1, the distance D2 and the angle θ related to the other first alignment mark 221. Further, the processing unit of the image measurement device may select an average value of the plurality of corrected distances D3 as the distance D3. This makes it possible to more accurately estimate the amount of protrusion of the light-emitting end surface 211 from the front surface 13 of the submount 10.

Last, whether sound or defective is determined. Determining whether sound or defective may be performed using an image measurement device. To be specific, when the distance D3 is within a predetermined value range, the processing unit of the image measurement device determines that the assembled light-emitting device 1 is a sound product. On the other hand, when the estimated distance D3 is outside a predetermined value range, the processing unit of the image measurement device determines that the assembled light-emitting device 1 is a defective product.

The processing unit of the image measurement device displays the determination result of whether the assembled light-emitting device 1 is a sound product or a defective product on a monitor or the like included in the image measurement device. The operator checks the monitor and selects the light-emitting device 1 determined to be sound. The processing unit of the image measurement device may output the determination result of whether the assembled light-emitting device 1 is a sound product or a defective product to, for example, a sorting device or the like incorporated in a manufacturing line of the light-emitting device 1. That is, sorting of the light-emitting devices 1 determined to be sound may be automated. Through these processes, the light-emitting device 1 is manufactured.

In the method for manufacturing the light-emitting device 1 according to the first embodiment, the distance D1 between the first alignment mark 221 and the light-emitting end surface 211 is determined in advance before disposing the bridge-shaped member 30. Accordingly, after the bridge-shaped member 30 is disposed, in a top view, even if the position of the light-emitting end surface 211 cannot be directly checked, it is possible to accurately confirm whether the distance between the light-emitting end surface 211 and the front surface 13 of the submount 10 is within a desired range. Here, for example, the first alignment mark 221 is disposed near the front surface 13 of the submount 10 or the light-emitting end surface 211. Thus, for example, one high-resolution image including the first alignment mark 221 and the light-emitting end surface 211 and one high-resolution image including the first alignment mark 221 and the front surface 13 of the submount 10 can be obtained using the image measurement device. Thus, the position information of the first alignment mark 221, the light-emitting end surface 211, and the front surface 13 of the submount 10 can be specified with high accuracy, and the distance D1, the distance D2, and the distance D3 can be measured with high accuracy. As a result, it is possible to suppress a situation in which the light emitted from the light-emitting end surface 211 is reflected by the submount 10 to cause a decrease in the intensity of the light in a desired irradiation range, a disturbance of a light distribution pattern, or the like, and it is possible to suppress a decrease in the heat dissipation efficiency of heat generated in the semiconductor laser element 20, thereby obtaining the light-emitting device 1 capable of efficient heat dissipation.

### Second Embodiment

### Example of Overall Configuration of Light-Emitting Device 1A

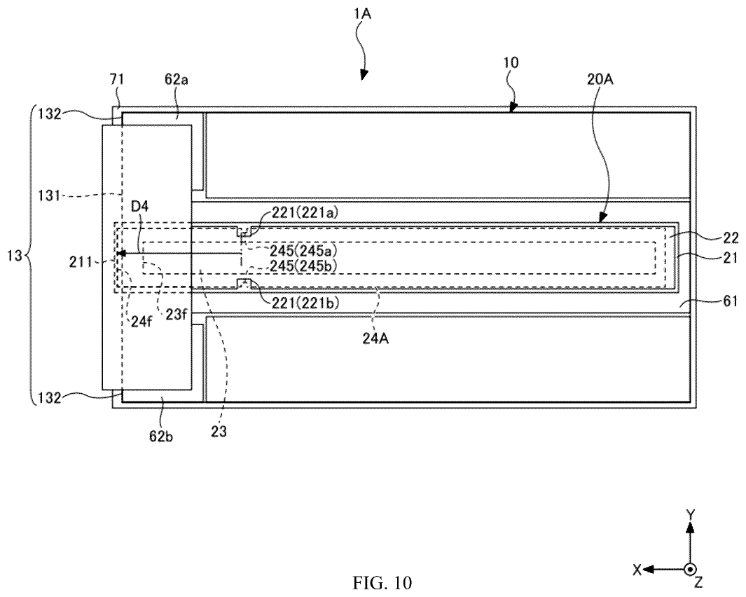

A light-emitting device 1A according to the second embodiment will be described with reference to FIG. 10. FIG. 10 is a schematic top view illustrating an example of the light-emitting device 1A according to the second embodiment. In the second embodiment, components that are similar to those in the first embodiment will be denoted by the same reference numerals, and descriptions thereof will be omitted as appropriate.

As illustrated in FIG. 10, the light-emitting device 1A includes the submount 10, a semiconductor laser element 20A, the bridge-shaped member 30, and the like. A pad electrode 24A of the semiconductor laser element 20A are provided a second alignment mark 245.

The second alignment mark 245 is arranged at a position away from a front end 24f of the pad electrode 24A by a distance D4 in the X-axis direction. Here, the pad electrode 24A and the second electrode 23 are formed on the lower surface of the semiconductor structure 21 so as to have a predetermined positional relationship. That is, the relative positional relationship between the pad electrode 24A and the second electrode 23 is obtained in advance as a design value. Thus, for example, if the position of the front end 24f of the pad electrode 24A is known, the position of the front end 23f of the second electrode 23 can be estimated. The distance D4 is an example of a “fourth distance”.

The illustrated pad electrode 24A includes two second alignment marks 245a and 245b. However, the number of the second alignment marks 245 is not limited to two. The second alignment mark 245a is a notch that is cut inward from the outer edge of the pad electrode 24A on the +Y side. The second alignment mark 245b is a notch that is cut inward from the outer edge of the pad electrode 24A on the −Y side. However, the second alignment marks 245a and 245b may be, for example, holes or the like having another shape such as a substantially circular shape, a substantially elliptical shape, or a substantially polygonal shape, which are disposed inside the pad electrode 24 so as not to be in contact with the outer edge of the pad electrode 24. The second alignment marks 245a and 245b can be easily formed by forming the second alignment marks 245a and 245b as regions vertically penetrating the pad electrode 24A in the form of a notch or hole. However, the second alignment marks 245a and 245b may not be regions vertically penetrating the pad electrode 24A. For example, the second alignment marks 245a and 245b may be patterns of a conductive film formed on the lower surface of the pad electrode 24A. The second alignment mark 245 may be formed by a forming method similar to that of the first alignment mark 221.

The second alignment mark 245a does not overlap with the first electrode 22 in a top view. For example, it is preferable that the second alignment mark 245a overlap with the first alignment mark 221a which is the cutout portion of the first electrode 22 in the top view. The semiconductor structure 21 disposed between the first electrode 22 and the pad electrode 24A transmits visible light. Thus, when the second alignment mark 245a overlaps with the first alignment mark 221a in a top view, the second alignment mark 245a can be visible from above. It is preferable that the second alignment mark 245b overlap with the first alignment mark 221b which is the cutout portion of the first electrode 22 in the top view. When the second alignment mark 245b overlaps with the first alignment mark 221b in a top view, the second alignment mark 245b can be visible from above. However, the second alignment marks 245a and 245b may be disposed at other positions that do not overlap with the first electrode 22 in a top view.

The second alignment marks 245a and 245b may each be a hole or the like with a substantially circular, substantially elliptical, or substantially polygonal shape vertically penetrating the pad electrode 24A. Also, the second alignment marks 245a and 245b may each be a pattern of a conductive film formed on the lower surface of the pad electrode 24A.

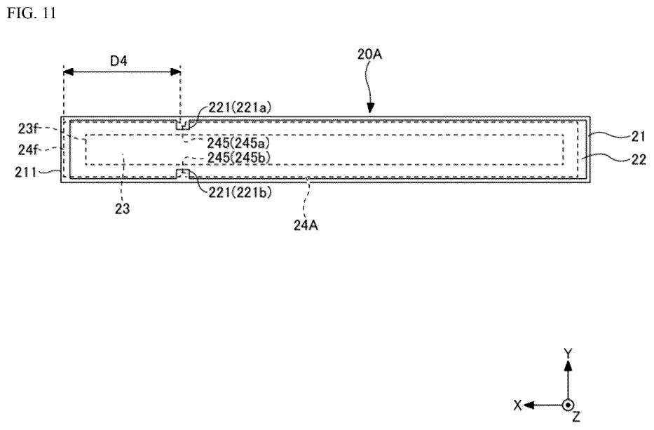

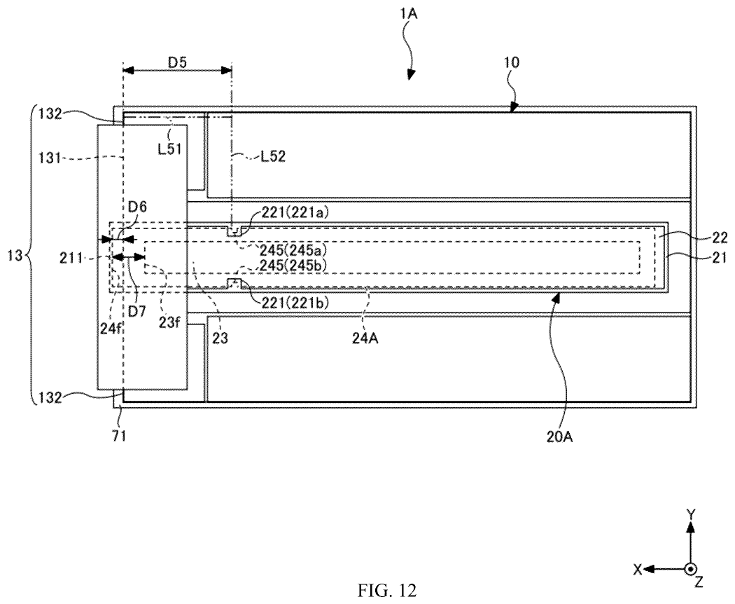

In order to efficiently dissipate heat generated in the second electrode 23 during the light-emitting operation of the semiconductor laser element 20A, it is preferable that the entire region of the lower surface of the second electrode 23 be joined to the upper surface 11 of the submount 10. In other words, the front end 23f of the second electrode 23 is preferably not located on the +X side relative to the front surface 13 of the submount 10. Although the front end 24f of the pad electrode 24A can be visible from above in the vicinity of the front end of the semiconductor laser element 20A because the semiconductor structure 21 transmits visible light, the position of the front end 24f of the pad electrode 24A cannot be checked after the light-emitting device 1A is assembled because the front end 24f of the pad electrode 24a is blocked by the bridge-shaped member 30. Thus, whether the front end 23f of the second electrode 23 is located on the −X side relative to the front surface 13 of the submount 10 cannot be estimated from the position of the pad electrode 24A. Thus, whether the front end 23f of the second electrode 23 is located on the −X side relative to the front surface 13 of the submount 10 is checked using the method described with reference to FIGS. 11 and 12.

### Method for Manufacturing Light-Emitting Device 1A

An example of a method for manufacturing the light-emitting device 1A according to the second embodiment will be described. The method for manufacturing the light-emitting device 1A according to the second embodiment is similar to that of the first embodiment and includes: preparing the submount 10, preparing the semiconductor laser element 20A, determining the distance D1 in the X-axis direction, disposing the semiconductor laser element 20A on the upper surface 11 of the submount 10, disposing the bridge-shaped member 30 on the upper surface 11 of the submount 10, measuring the distance D2 in the X-axis direction, calculating the distance D3 between the light-emitting end surface 211 and the front surface 13 of the submount 10, and determining whether the light-emitting device 1 is a sound product or a defective product. In addition, the method for manufacturing the light-emitting device 1A according to the second embodiment further includes: measuring the distance D4 between the front end 24f of the pad electrode 24A and the second alignment mark 245, measuring a distance D5 between the second alignment mark 245 and the front surface 13 of the submount 10, calculating a distance D6 between the front end 24f of the pad electrode 24A and the front surface 13 of the submount 10 from the subtraction value obtained by subtracting the distance D5 from the distance D4, and determining whether the light-emitting device 1A is a sound product or a defective product by comparing the distance D6 and a predetermined value.

Determining whether the light-emitting device 1A is a sound product or a defective product by comparing the distance D6 and the predetermined value may be the same as the determining whether sound or defective in the first embodiment or may be different. Measuring the distance D4 between the front end 24f of the pad electrode 24A and the second alignment mark 245 in the X-axis direction is hereinafter referred to as “measuring the distance D4”. Measuring the distance D5 in the X-axis direction between the second alignment mark 245 and the front surface 13 of the submount 10 is hereinafter referred to as “measuring the distance D5”. Calculating the distance D6 to the front surface 13 of the submount 10 is referred to as “calculating the distance D6”. The distance D5 is an example of a “fifth distance”. The distance D6 is an example of a “sixth distance”.

Measuring the distance D4 will be described with reference to FIG. 11. The measuring the distance D4 is performed between preparing the semiconductor laser element 20A and disposing the bridge-shaped member 30. FIG. 11 is a schematic top view illustrating an example of the semiconductor laser element 20A.

Here, the distance D4 is, for example, the shortest distance from the frontmost portion (the portion located at the most +X side) of the second alignment mark 245 to the front end 24f of the pad electrode 24A. However, the distance D4 may be a distance between another portion of the second alignment mark 245 and the front end 24f of the pad electrode 24A.

The distance D4 may be measured, for example, using an image measurement device. A method for measuring the distance D4 using the image measurement device is as follows, for example. First, the imaging unit of the image measurement device is disposed below the semiconductor laser element 20A and is caused to face, for example, the front region (region on the +X side) of the lower surface of the semiconductor laser element 20A. Subsequently, the imaging unit of the image measurement device captures an image including at least the front end 24f of the pad electrode 24A and the second alignment marks 245a and 245b. Subsequently, the imaging unit captures image data including the front end 24f of the pad electrode 24A and the second alignment marks 245a and 245b and outputs the image data to the processing unit. Subsequently, the processing unit measures the distance D4 between the front end 24f of the pad electrode 24A and the second alignment mark 245a or between the front end 24f of the pad electrode 24A and the second alignment mark 245b on the basis of the image data output from the imaging unit. Here, via analysis of the image data, the processing unit may automatically specify the position of the front end 24f of the pad electrode 24A and the positions of the second alignment marks 245a and 245b and measure the distance D4 from both pieces of specified position information. Also, the processing unit may measure the distance D4 on the basis of the position information of the front end 24f of the pad electrode 24A and the position information of the second alignment marks 245a and 245b input by an operator. The processing unit stores information of the measured distance D4.

The image measurement device may measure only the distance D4 between the second alignment mark 245a and the front end 24f of the pad electrode 24A. The image measurement device may measure only the distance D4 between the second alignment mark 245b and the front end 24f of the pad electrode 24A. Furthermore, the image measurement device may measure both the distance D4 between the second alignment mark 245a and the front end 24f of the pad electrode 24A and the distance D4 between the second alignment mark 245b and the front end 24f of the pad electrode 24A. Further, when the second alignment mark 245 is formed in addition to the second alignment marks 245a and 245b, the image measurement device may measure the distance D4 between the other second alignment mark 245 and the front end 24f of the pad electrode 24A. Further, the image measurement device may measure a distance between a line segment connecting the second alignment mark 245a and the second alignment mark 245b and the front end 24f of the pad electrode 24A and use the distance as the distance D4.

When the second alignment marks 245a and 245b are disposed near the front end 24f of the pad electrode 24A, the second alignment marks 245a and 245b and the front end 24f of the pad electrode 24A can be included in one high-resolution image even if the field of view of the imaging unit of the image measurement device is narrowed. As a result, the position information of the second alignment marks 245a and 245b and the position information of the front end 24f of the pad electrode 24A are specified with high accuracy. Accordingly, the distance D4 measurement accuracy can be increased.

Measuring the distance D5, calculating the distance D6, and determining whether sound or defective by comparing the distance D6 and the predetermined value will now be described with reference to FIG. 12. FIG. 12 is a schematic top view illustrating an example of the light-emitting device 1A including the submount 10, the semiconductor laser element 20A, and the bridge-shaped member 30.

By disposing the bridge-shaped member 30 on the submount 10, the light-emitting device 1A is assembled. Measuring the distance D5 is performed after disposing the bridge-shaped member 30. A method for measuring the distance D5 between the second alignment mark 245a, from among the two second alignment marks 245, and the front surface 13 of the submount 10 will be described as an example. Here, in FIG. 12, the distance D5 may be, for example, the distance in the X-axis direction between the second portion 132 and an imaginary line L52 extending along the Y-axis direction from the frontmost portion (the portion located at the most +X side) of the second alignment mark 245a. However, the distance D5 is not limited thereto. The distance D5 may be the distance between another portion of the second alignment mark 245a and the second portion 132.

The distance D5 is preferably measured, for example, using the image measurement device that measured the distance D4 and the like. A method for measuring the distance D5 using the image measurement device is as follows, for example. First, the imaging unit of the image measurement device is disposed above the light-emitting device 1A and is caused to face, for example, the front region (region on the +X side) of the light-emitting device 1A. Subsequently, the imaging unit of the image measurement device captures an image including at least the second portion 132 at the front surface 13 of the submount 10 and the second alignment mark 245a. Subsequently, the imaging unit outputs the image data including the second portion 132 and the second alignment mark 245a to the processing unit. Subsequently, the processing unit measures the distance D5 in the X-axis direction between the front surface 13 of the submount 10 whose position is specified from the second portion 132 and the second alignment mark 245a on the basis of the image data output from the imaging unit. Here, as when measuring the distance D4, the processing unit may automatically measure the distance D5 by analyzing the image data. Also, the processing unit may measure the distance D5 on the basis of the position information of the second portion 132 and the position information of the second alignment mark 245a input by an operator. The processing unit stores information of the measured distance D5. The image measurement device may execute similar processing to measure the distance D5 between the second alignment mark 245b and the front surface 13 of the submount 10.

When the second alignment marks 245a and 245b are disposed near the front surface 13 of the submount 10, the second alignment marks 245a and 245b and the second portion 132 of the front surface 13 can be included in one high-resolution image even if the field of view of the imaging unit of the image measurement device is narrowed. Accordingly, the position information of the second alignment marks 245a and 245b and the position information of the second portion 132 can be specified with high accuracy. As a result, the distance D5 measurement accuracy can be increased.

After measuring the distance D5, the distance D6 is calculated. Here, the front end 24f of the pad electrode 24A is covered with the bridge-shaped member 30 and is in a state of not being visible in a top view. Thus, the calculated distance D6 corresponds to an estimated value of the distance between the front end 24f of the pad electrode 24A and the front surface 13 of the submount 10.

To be more specific, for example, the processing unit of the image measurement device refers to the distance D4 and the distance D5 related to the second alignment mark 245a stored in a storage unit and obtains a subtraction value obtained by subtracting the distance D5 from the distance D4. The subtraction value obtained by the image measurement device is set as the distance D6 between the front end 24f of the pad electrode 24A and the front surface 13 of the submount 10. When the distance D4 is greater than the distance D5 and the distance D6 calculated as a result of subtracting the distance D5 from the distance D4 is “+”, it means that the front end 24f of the pad electrode 24A is on the +X side relative to the front surface 13 of the submount 10. When the distance D4 is less than the distance D5 and the distance D6 calculated as a result of subtracting the distance D5 from the distance D4 is “−”, it means that the front end 24f of the pad electrode 24A is on the −X side relative to the front surface 13 of the submount 10.

The processing unit of the image measurement device may calculate the distance D6 by referencing the distance D4 and the distance D5 related to the second alignment mark 245b. When the second alignment mark 245 is formed in addition to the second alignment marks 245a and 245b, the processing unit of the image measurement device may calculate the distance D6 by referencing the distance D4 and the distance D5 related to the other second alignment mark 245. The processing unit of the image measurement device may select, as the final distance D6, the largest value from among the plurality of distances D6 calculated on the basis of the distance D4 and the distance D5 for each second alignment mark 245. As in the first embodiment, the distance D6 may be corrected using information including the angle and the like between the front end 24f of the pad electrode 24A and the front surface 13 of the submount 10.

After calculating the distance D6, whether the light-emitting device 1A is a sound product or a defective product is determined by comparing the distance D6 and a predetermined value. It is known in advance that the front end 23f of the second electrode 23 is located away from the front end 24f of the pad electrode 24A by a distance D7 to the −X side. Thus, for example, by setting the predetermined value to the distance D7 and comparing the distance D6 and the predetermined value (distance D7), whether the front end 23f of the second electrode 23 is on the +X side relative to the front surface 13 of the submount 10 can be determined. To be specific, when the distance D6 is greater than the predetermined value, the front end 23f of the second electrode 23 is on the +X side relative to the front surface 13 of the submount 10. In this case, the processing unit of the image measurement device determines that the light-emitting device 1A is a defective product. On the other hand, when the distance D6 is equal to or less than the predetermined value, the front end 23f of the second electrode 23 is at the same position as the front surface 13 of the submount 10 or on the −X side relative to the front surface 13 of the submount 10. In this case, the processing unit of the image measurement device determines that the light-emitting device 1A is a sound product.

The processing unit of the image measurement device displays the determination result of whether the assembled light-emitting device 1A is a sound product or a defective product on a monitor or the like included in the image measurement device. The operator checks the monitor and selects the light-emitting device 1A determined to be sound. The processing unit of the image measurement device may output the determination result of whether the assembled light-emitting device 1A is a sound product or a defective product to, for example, a sorting device or the like incorporated in a manufacturing line of the light-emitting device 1A. That is, sorting of the light-emitting devices 1A determined to be sound may be automated. Through these processes, the light-emitting device 1A is manufactured.

In the method for manufacturing the light-emitting device 1A according to the second embodiment, the distance D4 between the second alignment mark 245 and the front end 24f of the pad electrode 24A is measured in advance before disposing the bridge-shaped member 30. Accordingly, after the bridge-shaped member 30 is disposed, in a top view, even if the position of the front end 24f of the pad electrode 24A cannot be directly checked, it is possible to confirm that the front end 23f of the second electrode 23 is not located on the +X side relative to the front surface 13 of the submount 10. Here, for example, the second alignment mark 245 is disposed near the front surface 13 of the submount 10 or the front end 24f of the pad electrode 24A. Thus, for example, one high-resolution image including the second alignment mark 245 and the front end 24f of the pad electrode 24A and one high-resolution image including the second alignment mark 245 and the front surface 13 of the submount 10 can be obtained using the image measurement device. Thus, the position information of the second alignment mark 245, the front end 24f of the pad electrode 24A, and the front surface 13 of the submount 10 can be specified with high accuracy, and the distance D4, the distance D5, and the distance D6 can be measured with high accuracy. As a result, it is possible to obtain the light-emitting device 1A in which a decrease in the heat dissipation efficiency of heat generated in the second electrode 23 is suppressed. That is, it is possible to obtain the light-emitting device 1A in which problems such as a decrease in the brightness of light emitted by the semiconductor laser element 20A and damage to the semiconductor laser element 20A are suppressed.

Although the preferred embodiments and the like have been described in detail above, the disclosure is not limited to the above-described embodiments and the like, various modifications and substitutions can be made to the above-described embodiments and the like without departing from the scope described in the claims.

What is claimed is:

1. A method for manufacturing a light-emitting device, the method comprising:
preparing a submount including an upper surface, a front surface connected to a front end of the upper surface, and a position specifying portion that specifies a position of the front surface in a top view;
preparing a semiconductor laser element including
a semiconductor structure having a light-emitting end surface, and
a first electrode disposed on an upper surface of the semiconductor structure and provided with a first alignment mark;
determining a first distance between the light-emitting end surface and the first alignment mark;
disposing the semiconductor laser element on the upper surface of the submount after the first distance is determined, the semiconductor laser element being disposed so that the light-emitting end surface protrudes from the front surface of the submount in the top view;
disposing a bridge-shaped member above the semiconductor laser element at a position overlapping with the light-emitting end surface and not overlapping with the first alignment mark and the position specifying portion in the top view;
measuring a second distance between the first alignment mark and the front surface of the submount from a position of the first alignment mark and a position of the front surface of the submount specified by the position specifying portion;
calculating a third distance between the light-emitting end surface and the front surface of the submount from a subtraction value obtained by subtracting the second distance from the first distance; and
determining whether the light-emitting device is a sound product or a defective product by comparing the third distance and a predetermined value.

2. The method for manufacturing a light-emitting device according to claim 1, wherein
the preparing of the semiconductor laser element includes preparing the first electrode including an additional first alignment mark so that a line segment connecting the first alignment mark and the additional first alignment mark is parallel to the light-emitting end surface in the top view, and
the calculating of the third distance includes correcting the third distance according to an angle formed by the front surface and the line segment.

3. The method for manufacturing a light-emitting device according to claim 1, wherein
the preparing of the submount includes preparing the submount so that the front surface of the submount includes a first portion overlapping with the bridge-shaped member and a second portion not overlapping with the bridge-shaped member in the top view, the second portion constituting the position specifying portion.

4. The method for manufacturing a light-emitting device according to claim 1, wherein
the preparing of the semiconductor laser element includes preparing the semiconductor laser element so that the first distance between the first alignment mark and the light-emitting end surface is 1000 μm or less.

5. The method for manufacturing a light-emitting device according to claim 1, wherein
the preparing of the semiconductor laser element includes preparing the semiconductor laser element so that the semiconductor laser element further includes
a second electrode disposed on a lower surface of the semiconductor structure, and
a pad electrode electrically connected to the second electrode and in contact with the lower surface of the semiconductor structure and the second electrode,
the second electrode and the pad electrode at least partially overlapping each other in the top view, and
the pad electrode including a second alignment mark not overlapping with the first electrode in the top view,
the method for manufacturing a light-emitting device further comprises:
measuring a fourth distance between a front end of the pad electrode and the second alignment mark;
measuring a fifth distance between the second alignment mark and the front surface of the submount from a position of the second alignment mark and a position of the front surface of the submount specified by the position specifying portion;
calculating a sixth distance between the front end of the pad electrode and the front surface of the submount from a subtraction value obtained by subtracting the fifth distance from the fourth distance; and
determining whether the light-emitting device is a sound product or a defective product by comparing the sixth distance and a predetermined value.

6. The method for manufacturing a light-emitting device according to claim 5, wherein
the preparing of the semiconductor laser element includes preparing the semiconductor laser element so that
the first alignment mark is a region of the first electrode vertically penetrating the first electrode, and
the second alignment mark is disposed at a position overlapping with the first alignment mark and not overlapping with the second electrode in the top view.

7. A light-emitting device comprising:
a submount including an upper surface, a front surface connected to a front end of the upper surface, and a position specifying portion that specifies a position of the front surface in a top view;
a semiconductor laser element disposed on the upper surface of the submount, the semiconductor laser element including
a semiconductor structure provided with a light-emitting end surface protruding from the front surface of the submount in the top view, and
a first electrode disposed on an upper surface of the semiconductor structure; and
a bridge-shaped member disposed on the upper surface of the submount, the bridge-shaped member overlapping with the light-emitting end surface and not overlapping with the position specifying portion in the top view, wherein
the first electrode includes a first alignment mark disposed at a position spaced apart from the light-emitting end surface by a first distance on a side opposite to the light-emitting end surface relative to the front surface of the submount and at the position not overlapping with the bridge-shaped member in the top view.

8. The light-emitting device according to claim 7, wherein
the front surface of the submount includes a first portion overlapping with the bridge-shaped member and a second portion not overlapping with the bridge-shaped member in the top view, and
the second portion constitutes the position specifying portion.

9. The light-emitting device according to claim 7, wherein
the first distance between the first alignment mark and the light-emitting end surface is 1000 μm or less.

10. The light-emitting device according to claim 7, wherein
the first electrode includes an additional first alignment mark.

11. The light-emitting device according to claim 10, wherein
a line segment connecting the first alignment mark and the additional first alignment mark is parallel to the light-emitting end surface in the top view.

12. The light-emitting device according to claim 7, wherein
the semiconductor laser element further includes
a second electrode disposed on a lower surface of the semiconductor structure, and
a pad electrode electrically connected to the second electrode and in contact with the lower surface of the semiconductor structure and the second electrode,
the second electrode and the pad electrode at least partially overlap each other in the top view, and
the pad electrode includes a second alignment mark disposed at a position away from a front end of the pad electrode by a fourth distance, the second alignment mark not overlapping with the first electrode in the top view.

13. The light-emitting device according to claim 12, wherein
the first alignment mark is a region of the first electrode vertically penetrating the first electrode, and
the second alignment mark is disposed at a position overlapping with the first alignment mark and not overlapping with the second electrode in a top view.
